(19) United States
(12) Patent Application Publication
(10) Pub. No.: US 2008/0254557 A1
(43) Pub. Date: Oct. 16, 2008

(54) Method for manufacturing lens for led package

(75) Inventors: Dong-Soo Kim, Ansan-si (KR); Hwa-Kyung Choi, Dalseong-gun (KR); Young-Seok Yoon, Seoul (KR)

Correspondence Address: NATH & ASSOCIATES, 112 South West Street, Alexandria, VA, 22314, US

(73) Assignee: ALTI-ELECTRONICS CO., LTD., Gyeonggi-do (KR)

(21) Appl. No.: 12/081,066

(22) Filed: Apr. 10, 2008

(30) Foreign Application Priority Data
Apr. 11, 2007 (KR) 10-2007-0035417

(51) Int. Cl. H01L 33/00

(52) U.S. Cl. 438/27; 257/E33.067

(57) ABSTRACT

A method for manufacturing a lens for a light emitting diode (LED) package is disclosed. The method for manufacturing a lens for an LED package includes: forming a dome lens on each of a plurality of LED packages placed on a fixing plate, the dome lens made of silicon; forming a concave groove in the dome lens by using a jig for pressing the dome lens; curing the dome lens; and removing the LED packages from the fixing plate.

### CROSS-REFERENCE TO RELATED APPLICATION

This application claims priority to and the benefit of Korean Patent Application No. 2007-35417, filed on Apr. 11, 2007, the disclosure of which is incorporated herein by reference in its entirety.

### BACKGROUND OF THE INVENTION

1. Field of the Invention

The present invention relates to a light emitting diode (LED) package, and more particularly, to a method for manufacturing a lens for an LED package in which a manufacturing process is simplified.

2. Description of the Related Art

A liquid crystal display (LCD) device displays an image such that an electric power is applied to each pixel to change an alignment of liquid crystal molecules. An LCD device is a non-emissive display device and so needs a backlight unit which uniformly irradiates light to a display panel so that it can be used even in a dark place.

The backlight unit comprises a light source like a fluorescent lamp or a light emitting diode (LED), a light guide plate, and a prism sheet.

In case of an LED, an LED package in which an LED chip is mounted to a lead frame, a fluorescent material is inserted, and a special material is injected to mount and mold the LED chip is provided as a light source.

FIG. 1A shows an orientation angle of a conventional LED package having no lens.

Referring to FIG. 1A, light emitted from the LED package having no lens is condensed at a certain orientation angle. The LED package has low light efficiency because a total reflection of light occurs in an interface between a molded upper surface and an air and so lots of light go back to an inside of the LED package.

In order for the LED package to have a better performance, light emitted from the LED package should have an orientation pattern of a fan shape. The orientation pattern of a fan shape can be achieved by an appropriate package design. Also, in order to increase light efficiency, a dome lens is mounted onto an LED package.

FIG. 1B shows an orientation angle of a conventional LED package having a dome lens.

Referring to FIG. 1B, an orientation pattern of emitted light is wider than that of FIG. 1A. The dome lens condenses and then irradiates light totally reflected in the LED package, so that a wider orientation angle is obtained. The dome lens is typically made of a plastic material such as polycarbonate (PC) or Polymethylmethaclylate (PMMA). The dome lens is mounted onto the LED package by using an adhesive. An interface and a fine gape are formed between the dome lens and the LED package since a material of the dome lens and a molding material molded in the LED package are different and the dome lens and the LED package are mounted by using an adhesive.

However, in such a conventional LED package having the dome lens, a process for manufacturing the dome lens and a process for attaching the dome lens to the LED package are very complicated. In addition, since an interface and a fine gape are formed between the dome lens and the LED package, light efficiency is low due to a refraction index difference.

### SUMMARY OF THE INVENTION

It is an object of the present invention to provide a method for manufacturing a lens for an LED package in which a manufacturing process is simple. It is another object of the present invention to provide a method for manufacturing a lens for an LED package in which the thickness and volume of a backlight unit employing the LED package are reduced and the brightness is increased.

An exemplary embodiment of the present invention provides a method for manufacturing a lens for a light emitting diode (LED) package, comprising: forming a dome lens on each of a plurality of LED packages placed on a fixing plate, the dome lens made of silicon; forming a concave groove in the dome lens by using a jig for pressing the dome lens; curing the dome lens; and removing the LED packages from the fixing plate.

The dome lens is formed by using a dispensing technique or a printing technique.

The dome lens is made of transparent silicon having viscosity enough for the dome lens to have a dome shape and not to stream down to the LED package.

The viscosity of the dome lens is 30 to 50 Pas.

The dome lens is cured at a temperature of 140° C. to 160° C. for 25 to 35 minutes.

A distance between an optical sheet and an LED chip is reduced in consideration of an orientation angle of light emitted from the dome lens.

The concave groove has a shape which provides an orientation angle at which light emitted from the LED package is widely spread.

The concave groove has a predetermined angle.

The step for forming the concave groove in the dome lens comprises moving an upper plate jig having a plurality of projection formed on a bottom thereof with a corresponding shape at locations corresponding to the plurality of LED packages down to a lower plate jig which supports the fixing plate to press the dome lens.

The upper plate jig moves down to the lower plate jig to press the dome lens, the concave groove is formed corresponding to the height of a press arm of the upper plate jig for restricting the pressing range.

The projection has a corn shape.

Each of the plurality of LED packages is formed such that an LED chip is mounted to a lead frame, a fluorescent material is inserted, and one of synthetic resin, transparent epoxy or silicon is injected to mount and mold the LED chip.

### BRIEF DESCRIPTION OF THE DRAWINGS

The above and other features of the present invention will be described in reference to certain exemplary embodiments thereof with reference to the attached drawings in which:

FIG. 1A shows an orientation angle of a conventional LED package having no lens;

FIG. 1B shows an orientation angle of a conventional LED package having a dome lens;

FIG. 2A is a side view illustrating a dome lens according to an exemplary embodiment of the present invention;

FIG. 2B is a side view illustrating a modified dome lens according to the exemplary embodiment of the present invention.

FIG. 3 shows an orientation angle of light emitted from a backlight unit having the LED package in which one of the dome lenses of FIGS. 2a and 2b is employed;

FIG. 4 is a perspective view illustrating a jig for forming a concave groove in the dome lens according to the exemplary embodiment of the present invention;

FIG. 5 is a flowchart illustrating a method for manufacturing the lens for the LED package according to the exemplary embodiment of the present invention;

FIGS. 6A to 6F are perspective views illustrating the method for manufacturing the lens for the LED package according to the exemplary embodiment of the present invention;

FIG. 7 is a flowchart illustrating a process for forming the concave groove in the dome lens according to the exemplary embodiment of the present invention; and

FIG. 8 is a flowchart illustrating a curing process according to the exemplary embodiment of the present invention.

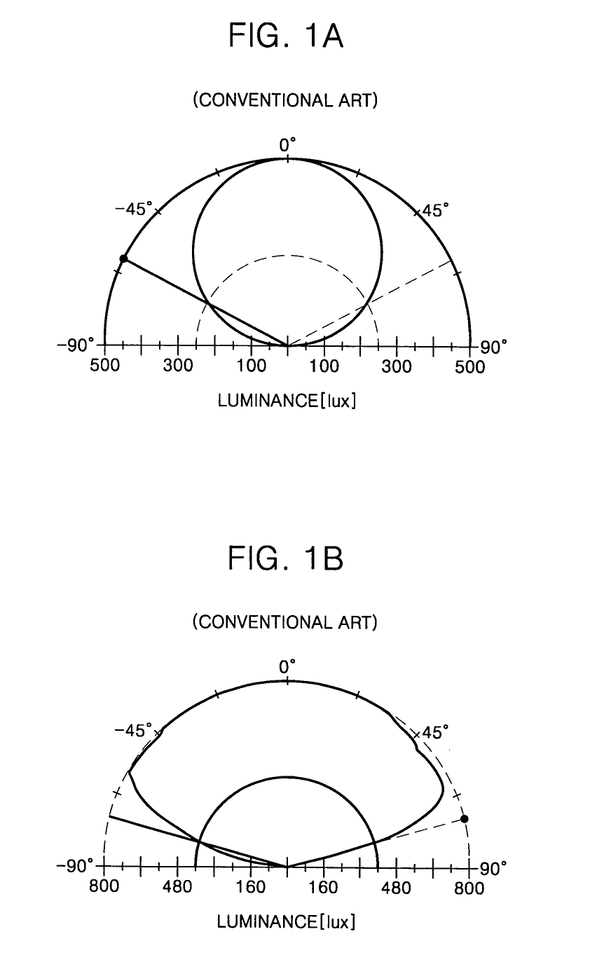

### DETAILED DESCRIPTION OF THE INVENTION

Reference will now be made in detail to the embodiments of the present invention, examples of which are illustrated in the accompanying drawings, wherein like reference numerals refer to the like elements throughout. The embodiments are described below in order to explain the present invention by referring to the figures.

According to the present invention, an LED chip is mounted to a lead frame through a die bonding (D/B) and wire boding (W/B), and the LED chip is molded by silicon. A dome lens of a dome shape is manufactured on the LED package by silicon. The dome lens is manufactured by a dispensing technique or a printing technique. The LED package having the dome lens is located between upper and lower plate jigs, and the upper plate jig moves down toward the lower plate jig to thereby forming a concave groove in the dome lens. In this pressed state, the concave grove is cured.

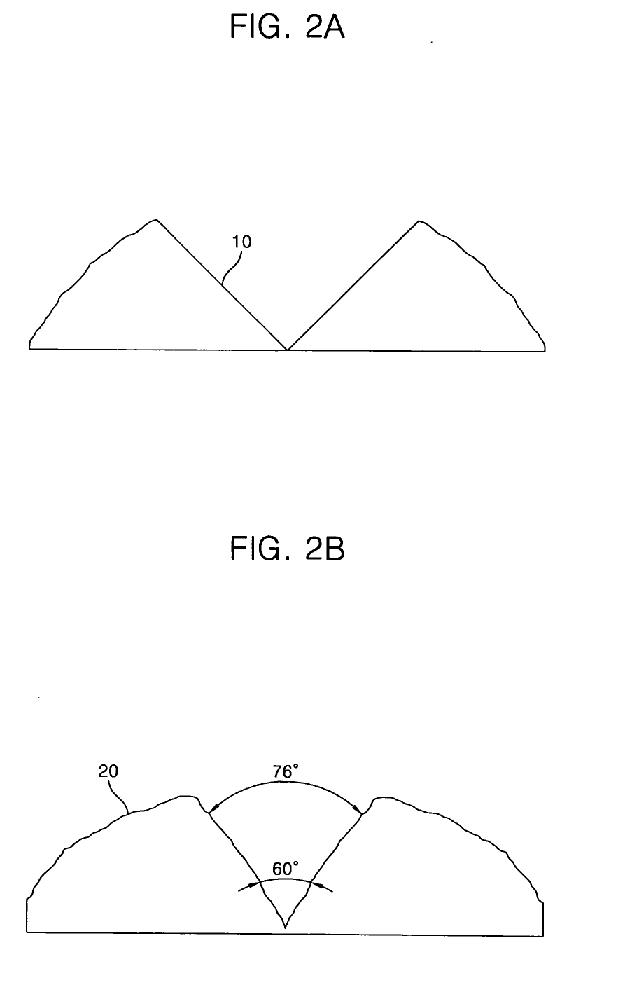

FIG. 2A is a side view illustrating a dome lens according to an exemplary embodiment of the present invention, and FIG. 2B is a side view illustrating a modified dome lens according to the exemplary embodiment of the present invention.

Referring to FIGS. 2A and 2B, a dome lens is manufactured on an LED package by using silicon with predetermined viscosity. Here, silicon has viscosity enough for the dome lens to have a dome shape and not to stream down to the LED package. Preferably, silicon has viscosity of about 30 to 50 Pas. The dome lenses 10 and 20 may be manufactured by using a dispensing technique or a printing technique. The dispensing and printing techniques are well known to a person having ordinary skill in the art.

A concave groove of a predetermined shape is formed in the dome lens by a projection attached to a bottom of an upper plate jig, which will be described in detail later.

For example, if a concave groove of a corn shape having a predetermined angle is formed in the dome lens 10 as shown in FIG. 2a, light emitted from the LED package has a wide orientation angle. Thus, a color mixing between light sources of a backlight unit BLU having the dome lens for the LED package is increased, and light uniformity is increased, so that the thickness of the backlight unit can be reduced. That is, the thickness of the backlight unit can be reduced since an orientation angle of light emitted from the LED package is widened by the dome lens having the concave groove and so a distance between an optical sheet (not shown) and the LED package can be minimized.

A concave groove formed in the dome lens 20 of FIG. 2B has an angle which depends on the height or depth of the dome lens 20.

For example, the concave groove has an angle of 60° at the low height and an angle of 76° at the high height. The concave groove having different angles according to the height of the dome lens 20 can be formed by a projection of the upper plate jig corresponding to the concave groove.

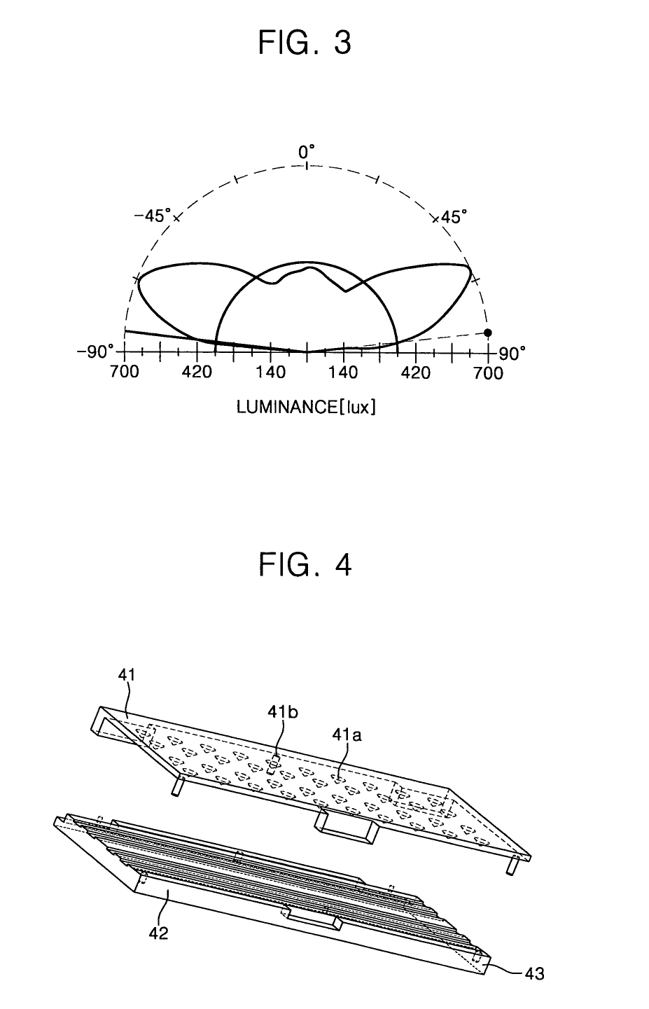

If the dome lenses 10 and 20 for the LED package of FIGS. 2a and 2b are employed to the backlight unit, an orientation angle of light emitted from the LED package is widened. It can be understood in FIG. 3 that a curve of an orientation angle is wider spread compared to the conventional LED package having the dome lens. FIG. 3 shows an orientation angle of light emitted from the backlight unit having the LED package in which one of the dome lenses 10 and 20 of FIGS. 2a and 2b is employed. The dome lenses 10 and 20 of FIGS. 2A and 2B may have different orientation angles.

FIG. 4 is a perspective view illustrating the jig for forming the concave groove in the dome lens according to the exemplary embodiment of the present invention.

Referring to FIG. 4, the jig comprises an upper plate jig 41 and a lower plate jig 42.

The upper plate jig 41 comprises a plurality of projections 41a formed on a bottom thereof. A plurality of projections 41a are formed with a corresponding shape at locations corresponding to a plurality of LED packages. The upper plate jig 41 further comprises a press arm 41b which restricts a range for pressing the dome lenses 10 and 20 in a direction of the lower plate jig 42. Here, the length of the press arm 41b is determined in consideration of the concave groove to be formed in the dome lenses 10 and 20.

The lower plate jig 42 supports a fixing plate (not shown) on which a plurality of LED packages are placed. The lower plate jig 42 comprises a coupling portion 43 to be coupled to the press arm 41 b when pressed.

An operation of the jig for forming the concave groove in the dome lens according to the exemplary embodiment of the present invention is described with reference to FIG. 4.

The fixing plate on which a plurality of LED packages are placed is located between the upper plate jig 41 and the lower plate jig 42. The upper plate jig 41 moves down toward the lower plate jig 42 to press the dome lens 10 mounted on the LED package 100 in a concave groove form until it is stopped by the press arm 41b. As a result, the concave groove is formed in the dome lens 10 by the projection 41 of the upper jig 41. In the pressed state, the dome lens 10 is subjected to a curing process. The curing process is preferably performed at a temperature of 140˜160° C. for 25 to 35 minutes.

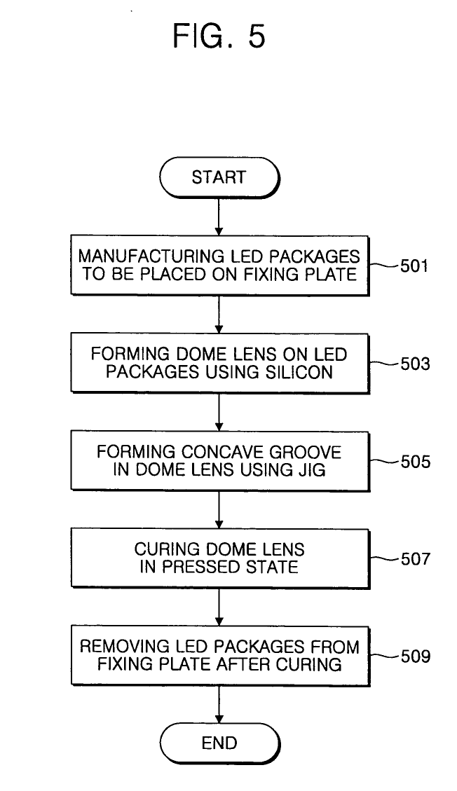

Hereinafter, a method for manufacturing the lens for the LED package according to the exemplary embodiment of the present invention is described in more detail with reference to FIGS. 5 to 8.

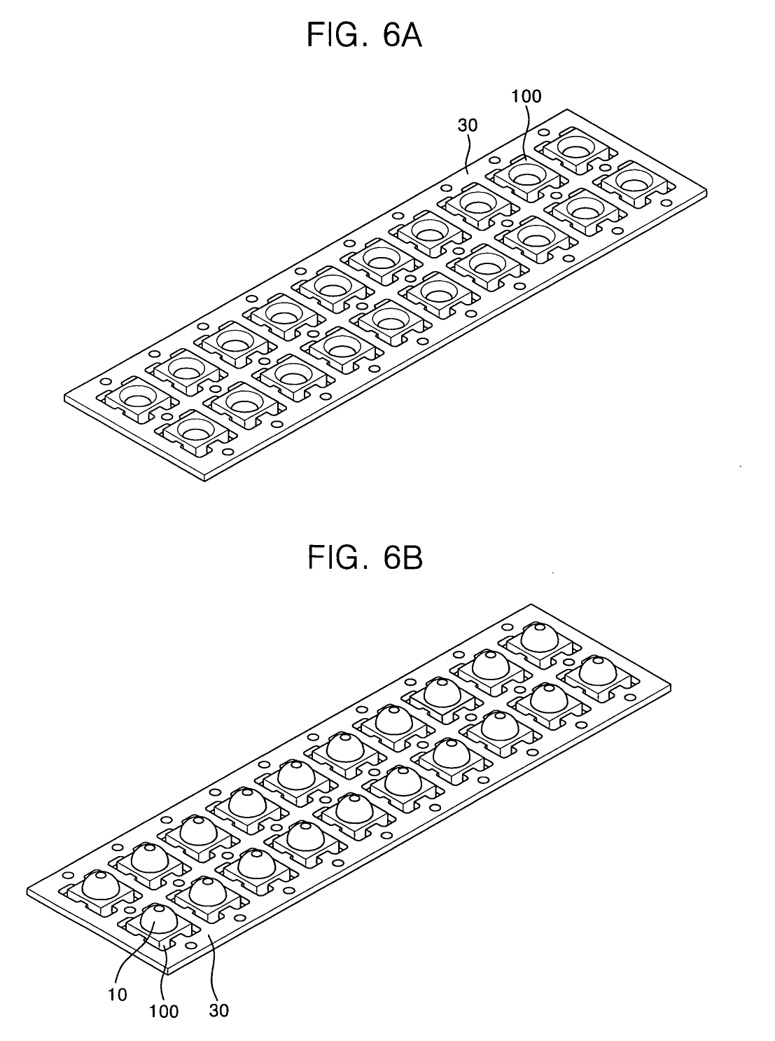

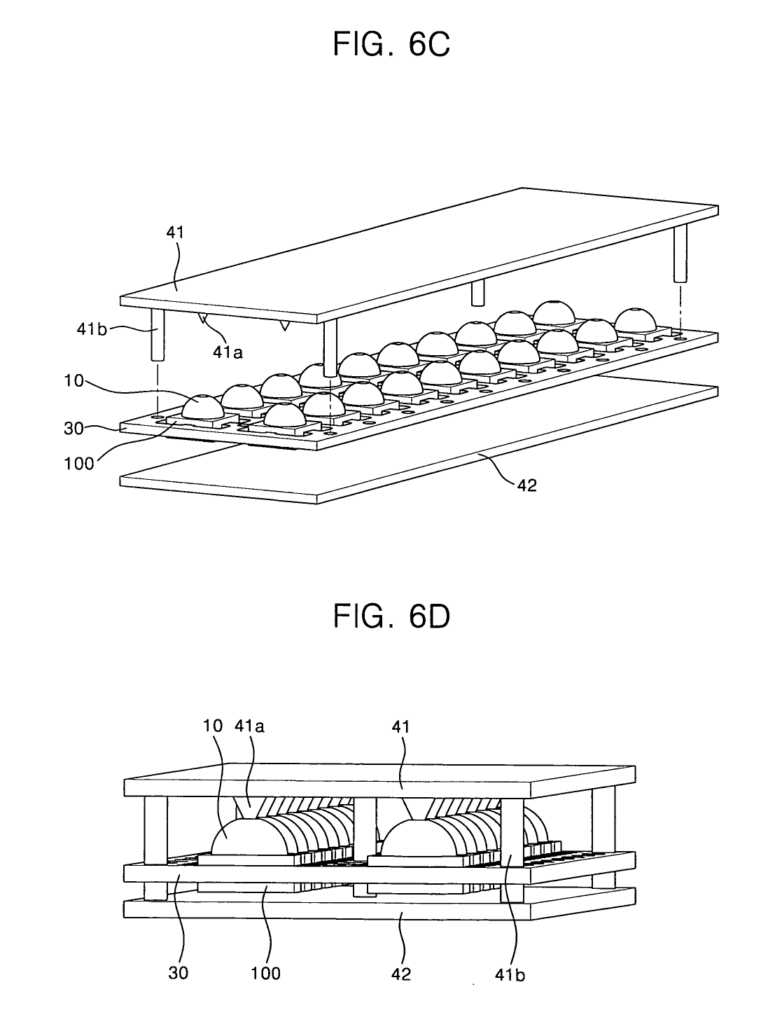

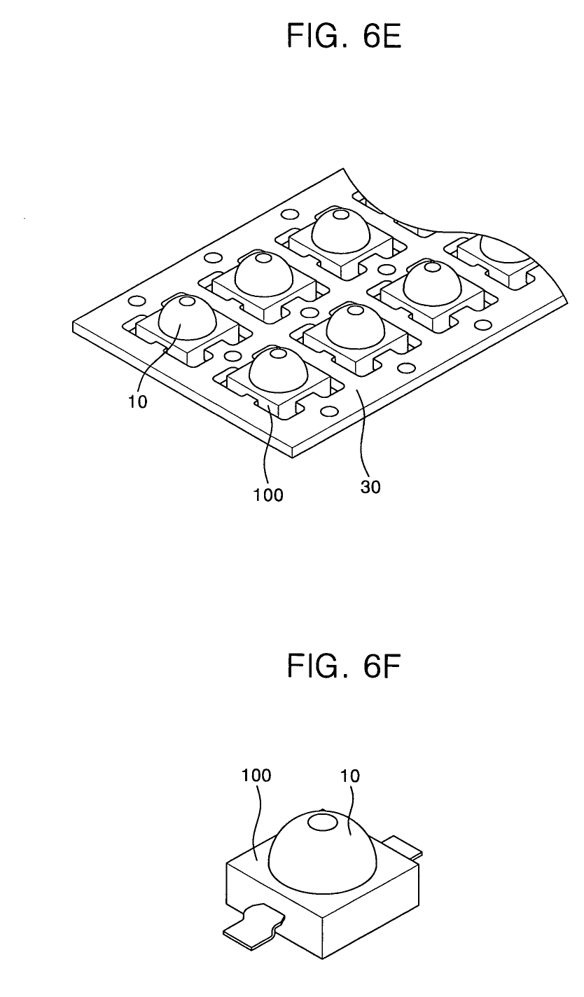

FIG. 5 is a flowchart illustrating a method for manufacturing the lens for the LED package according to the exemplary embodiment of the present invention, and FIGS. 6a to 6f are perspective views illustrating the method for manufacturing the lens for the LED package according to the exemplary embodiment of the present invention.

First, as shown in FIG. 6A, a plurality of LED packages 100 to be placed on the fixing plate 30 are manufactured (step 501).

As shown in FIG. 6B, dome lenses 10 are formed on a plurality of LED packages 100 by using silicon (step 503). The silicon is transparent silicon and has viscosity enough for the dome lens 10 to have a dome shape and not to stream down to the LED package. Preferably, the silicon has viscosity of 30 to 50 Pas.

The dome lens 10 is located between the upper and lower plate jigs 41 and 42 as shown in FIG. 6C, and the concave groove is formed in the dome lens 10 by the projection 41a of the upper plate jig 41 as shown in FIG. 6D (step 505).

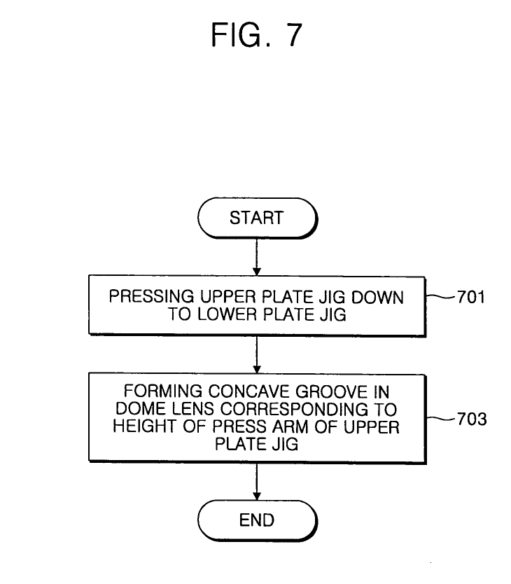

The process for forming the concave groove in the dome lens is described with reference to FIG. 7. FIG. 7 is a flowchart illustrating a process for forming the concave groove in the dome lens according to the exemplary embodiment of the present invention.

When the dome lens 10 is located between the upper and lower plate jigs 41 and 42, the upper plate jig 41 moves down toward the lower plate jig 42 to press the dome lens 10 (step 701), and the press arm 41b of the upper plate jig 41 penetrates the fixing plate 30 to be coupled to the coupling portion 43 of the lower plate jig 42. At this time, the projection 41a of the upper plate jig 41 forms the concave groove in the dome lens 10 (step 703).

Returning now to FIG. 5, the dome lens 10 having the concave groove formed by the upper and lower plate jigs 41 and 42 is subject to a curing process (step 507).

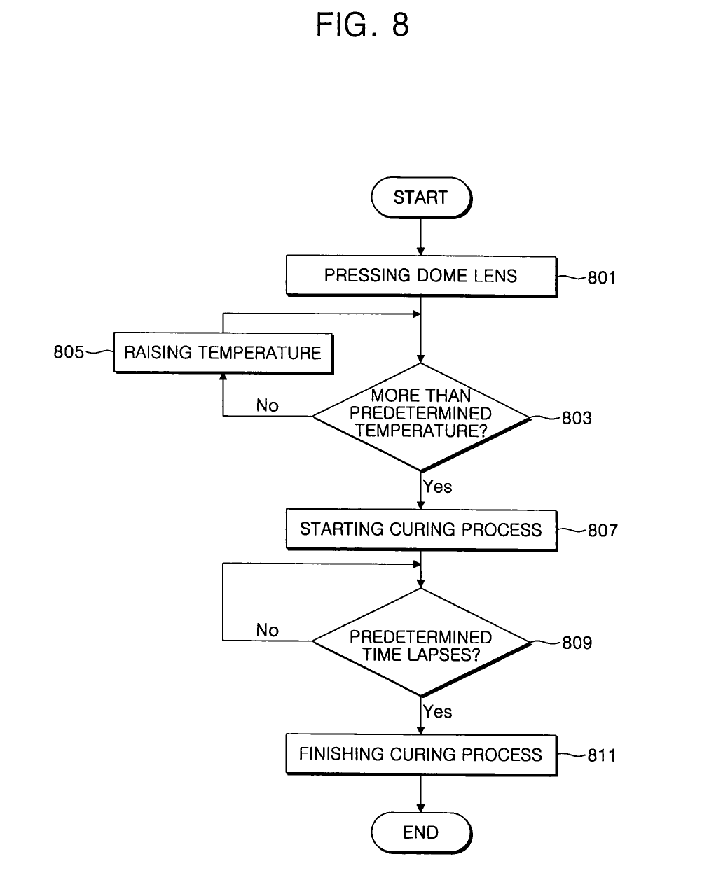

The process for curing the dome lens 10 is described with reference to FIG. 8. FIG. 8 is a flowchart illustrating the curing process according to the exemplary embodiment of the present invention.

In a state that the dome lens 10 is pressed by the projection 41a of the upper plate jig 41 (step 801), it is determined whether it is more than a predetermined temperature or not (step 803).

If not, a temperature is increased until it is more than a predetermined temperature (step 805).

However, if it is more than a predetermined temperature, a curing of the dome lens 10 begins (step 807).

It is determined whether a predetermined time lapses or not (step 809). If so, a curing of the dome lens 10 stops (step 811). However, if not, a curing of the dome lens 10 is continuously performed until a predetermined time lapses.

If the dome lens 10 is completely cured, the upper plate jig 41 which is pressing the dome lens 10 is detached from the lower plate jig 42 as shown in FIG. 6E. Then, as shown in FIG. 6F, a plurality of LED packages 100 having the dome lens 10 are removed from the fixing plate 30 (step 509).

As described above, according to the present invention, since the concave groove is formed in the dome lens by the jig, the dome lens having excellent light efficiency and brightness can be manufactured, and the manufacturing process of the dome lens can be simplified.

In addition, the thickness of the backlight unit which employs the LED package having the dome lens can be reduced.

Although the present invention has been described with reference to certain exemplary embodiments thereof, it will be understood by those skilled in the art that a variety of modifications and variations may be made to the present invention without departing from the spirit or scope of the present invention defined in the appended claims, and their equivalents.

What is claimed is:

1. A method for manufacturing a lens for a light emitting diode (LED) package, comprising:
forming a dome lens on each of a plurality of LED packages placed on a fixing plate, the dome lens made of silicon;
forming a concave groove in the dome lens by using a jig for pressing the dome lens;
curing the dome lens; and
removing the LED packages from the fixing plate.

2. The method of claim 1, wherein the dome lens is formed by using a dispensing technique or a printing technique.

3. The method of claim 2, wherein the dome lens is made of transparent silicon having viscosity enough for the dome lens to have a dome shape and not to stream down to the LED package.

4. The method of claim 3, wherein the viscosity of the dome lens is 30 to 50 Pas.

5. The method of claim 1, wherein the dome lens is cured at a temperature of 140° C. to 160° C. for 25 to 35 minutes.

6. The method of claim 1, wherein the concave groove has a shape which provides an orientation angle at which light emitted from the LED package is widely spread.

7. The method of claim 6, wherein the concave groove has a predetermined angle.

8. The method of claim 1, wherein the step for forming the concave groove in the dome lens comprises moving an upper plate jig having a plurality of projection formed on a bottom thereof with a corresponding shape at locations corresponding to the plurality of LED packages down to a lower plate jig which supports the fixing plate to press the dome lens.

9. The method of claim 8, wherein when the upper plate jig moves down to the lower plate jig to press the dome lens, the concave groove is formed corresponding to the height of a press arm of the upper plate jig for restricting the pressing range.

10. The method of claim 8, wherein the projection has a corn shape.

11. The method of claim 1, wherein each of the plurality of LED packages is formed such that an LED chip is mounted to a lead frame, a fluorescent material is inserted, and one of synthetic resin, transparent epoxy or silicon is injected to mount and mold the LED chip.
